(19) United States
(12) Patent Application Publication
(10) Pub. No.: US 2014/0077195 A1
(43) Pub. Date: Mar. 20, 2014

(54) ORGANIC LIGHT-EMITTING DIODE PACKAGE STRUCTURE AND METHOD OF MANUFACTURING CONCAVITY ON SUBSTRATE

(71) Applicants: Wintek Corporation, Taichung City (TW); Dongguan Masstop Liquid Crystal Display Co., Ltd., Dongguan City (CN)

(72) Inventors: Yan-Yu Su, Changhua County (TW); Jyh-Yeuan Ma, Taoyuan County (TW); Chia-Hsiung Chang, Tainan City (TW); Chong-Yang Fang, Taichung City (TW)

(73) Assignees: Wintek Corporation, Taichung City (TW); Dongguan Masstop Liquid Crystal Display Co., Ltd., Dongguan City (CN)

(21) Appl. No.: 14/027,157

(22) Filed: Sep. 14, 2013

(30) Foreign Application Priority Data
Sep. 14, 2012 (TW) 101133696

(51) Int. Cl. H01L 51/52; H01L 51/56

(52) U.S. Cl. CPC H01L 51/52; H01L 51/56
USPC 257/40; 438/689; 438/795

(57) ABSTRACT

The present invention provides an organic light-emitting diode package structure including a first substrate, a second substrate, at least an organic light-emitting diode device and a dam. The first substrate and a surface of the second substrate are disposed opposite to each other, wherein the surface of the second substrate includes a plurality of concavities, each of the concavities has an opening area, and a ratio of a sum of the opening areas of the concavities to an area of the first surface of the second substrate is substantially between 0 and 1. The organic light-emitting diode device is disposed on the first substrate, and a light emitting surface of the organic light-emitting diode device faces the second substrate. The dam is disposed between the first substrate and the second substrate to combine the first substrate and the second substrate, and the dam surrounds the organic light-emitting diode device.

### BACKGROUND OF THE INVENTION

1. Field of the Invention

The present invention relates to an organic light-emitting diode package structure and a method of forming concavities on a substrate, and more particularly, to an organic light-emitting diode package structure including an upper substrate having an inner surface with concavities, and a method of forming concavities on a substrate.

2. Description of the Prior Art

The organic light-emitting diode device is a self emission device and includes the characteristics such as light and thin structure, low power consumption, fast response time and flexibility. Therefore, the organic light-emitting diode device can be widely applied in the filed of lighting or display devices.

In the conventional organic light-emitting diode package structure, the organic light-emitting diode device is enclosed by an upper transparent substrate, a lower transparent substrate and a dam. Due to the difference of the refractive indexes between different material layers, light emitted from an organic light-emitting layer of the organic light-emitting diode device may suffer the problem resulted from reflection or refraction, and therefore, the produced light may not be totally emitted from the transparent substrates. Accordingly, a method of forming lens matrix on an upper surface of the upper transparent substrate has been developed to reduce the occurrence of total reflection as the light moves into the air from the upper transparent substrate.

However, the convex lens matrix disposed on the upper surface of the upper transparent substrate often suffers scratch damage during the manufacturing process or during the moving process, which may reduce the luminance of the light emitted from the convex lens matrix. Furthermore, when the conventional organic light-emitting diode package structure is used in the display device, since the convex lens matrix is disposed on the upper surface of the upper transparent substrate, the light produced by the organic light-emitting diode device may be emitted to the neighboring convex lens matrix which is corresponding to the neighboring pixel, thereby causing the interference of the images displayed by the neighboring pixels. Therefore, another method of disposing the convex lens matrix on the organic light-emitting diode device has been developed, but this disposition of the convex lens matrix may increase the overall thickness of the organic light-emitting diode package structure.

Consequently, how to reduce the overall thickness of the organic light-emitting diode package structure, and simultaneously increase the light extraction efficiency of the organic light-emitting diode package structure, is still an important issue in this field.

### SUMMARY OF THE INVENTION

An objective of the present invention is therefore to provide an organic light-emitting diode package structure and a method of forming concavities on a substrate to reduce the overall thickness of the organic light-emitting diode package structure and simultaneously increase the light extraction efficiency of the organic light-emitting diode package structure.

According to one exemplary embodiment of the present invention, an organic light-emitting diode package structure is provided. The organic light-emitting diode package structure includes a first substrate, a second substrate, at least an organic light-emitting diode device and a dam. The second substrate has a first surface and a second surface, and the first surface of the second substrate and the first substrate are disposed opposite to each other, in which the first surface of the second substrate includes a plurality of concavities, wherein each of the concavities has an opening area, and a ratio of a sum of the opening areas of the concavities to an area of the first surface of the second substrate is substantially between 0 and 1. The organic light-emitting diode device is disposed on the first substrate, and a light emitting surface of the organic light-emitting diode device faces the second substrate. The dam is disposed between the first substrate and the second substrate to combine the first substrate and the second substrate, and the dam surrounds the organic light-emitting diode device.

According to another exemplary embodiment of the present invention, a method of forming concavities on a substrate is provided. A substrate is provided. A photoresist pattern is formed on the substrate, and the photoresist pattern includes a plurality of openings exposing the substrate. An etching process is performed to etch the substrate through each of the openings to form a plurality of concavities. Afterwards, the photoresist pattern is removed.

According to another exemplary embodiment of the present invention, a method of forming concavities on a substrate is provided. A substrate is provided. An adhesive film is coated on the substrate. A mold including a plurality of protrusions is provided. Subsequently, a surface including the protrusions of the mold is pressed to the adhesive film to form a plurality of concavities in the adhesive film. Afterwards, a curing process is performed to cure the adhesive film, and the mold is removed.

The concavities are formed on the first surface of the second substrate to serve as concave lens surfaces. The disposition of the concavities can reduce the occurrence of total reflection as the light emitted from the light emitting surface of the organic light-emitting diode device moves into the second substrate, to increase the light extraction efficiency of the organic light-emitting diode package structure. Furthermore, the concavities are used as the lens surfaces to converge light rather than convex lens surface in the organic light-emitting diode package structure, which may validly reduce the overall thickness of the organic light-emitting diode package structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional view of an organic light-emitting diode package structure according to a first exemplary embodiment of the present invention.

FIG. 2 is a top view of an organic light-emitting diode package structure according to a first exemplary embodiment of the present invention.

FIG. 3 is a cross-sectional view of an organic light-emitting diode package structure according to a second exemplary embodiment of the present invention.

FIG. 4 is a cross-sectional view of an organic light-emitting diode package structure according to a third exemplary embodiment of the present invention.

FIG. 5 is a cross-sectional view of an organic light-emitting diode package structure according to a fourth exemplary embodiment of the present invention.

FIG. 6 is a cross-sectional view of an organic light-emitting diode package structure according to a fifth exemplary embodiment of the present invention.

FIG. 7 is a top view of an organic light-emitting diode package structure according to a fifth exemplary embodiment of the present invention.

FIG. 8 is a cross-sectional view of an organic light-emitting diode package structure according to a sixth exemplary embodiment of the present invention.

FIG. 9 through FIG. 11 are schematic diagrams of a method of forming concavities according to a preferred exemplary embodiment of the present invention.

FIG. 12 through FIG. 14 are schematic diagrams of a method of forming concavities according to another preferred exemplary embodiment of the present invention.

### DETAILED DESCRIPTION

To provide a better understanding of the present invention, preferred exemplary embodiments will be described in detail. The preferred exemplary embodiments of the present invention are illustrated in the accompanying drawings with numbered elements.

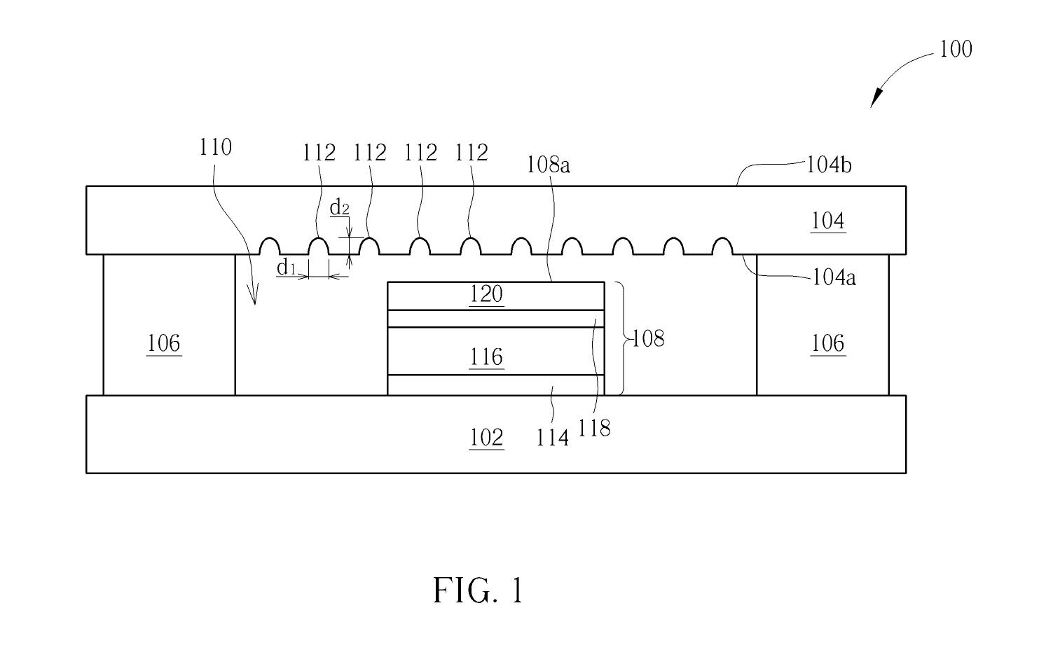

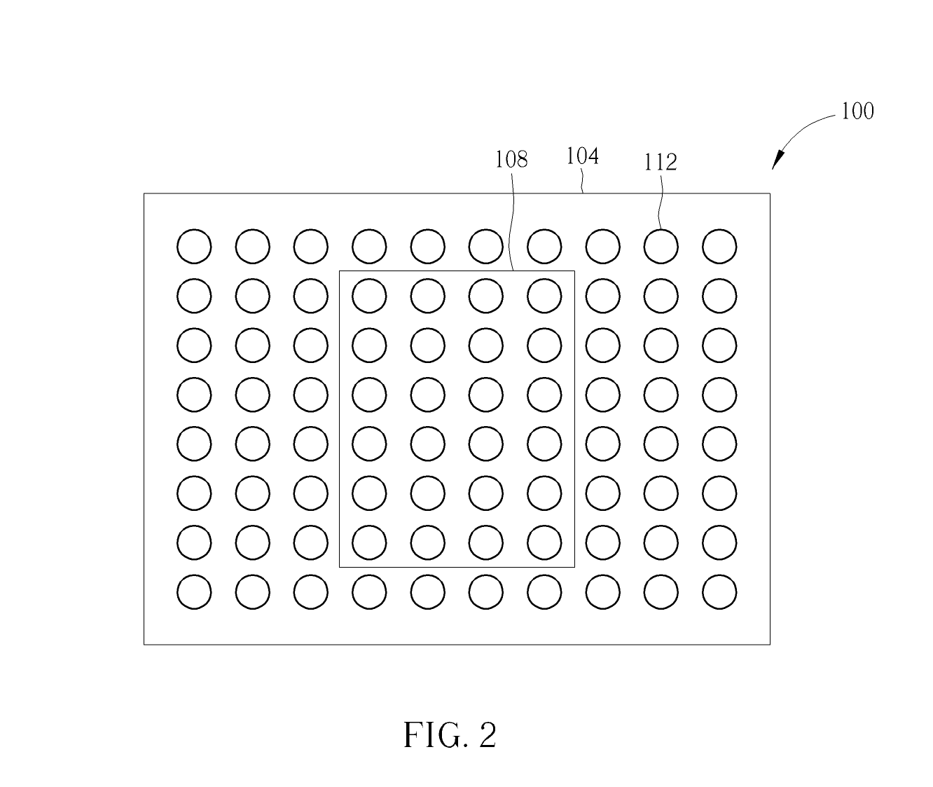

Please refer to FIG. 1 and FIG. 2. FIG. 1 illustrates a cross-sectional view of an organic light-emitting diode package structure according to a first exemplary embodiment of the present invention. FIG. 2 illustrates a top view of an organic light-emitting diode package structure according to a first exemplary embodiment of the present invention. As shown in FIG. 1 and FIG. 2, the organic light-emitting diode package structure 100 includes a first substrate 102, a second substrate 104, a dam 106 and at least an organic light-emitting diode device 108. The second substrate 104 has a first surface 104a and a second surface 104b, and the first surface 104a of the second substrate 104 and the first substrate 102 are disposed opposite to each other. In this exemplary embodiment, the first substrate 102 and the second substrate 104 can respectively be transparent substrates such as glass substrates, plastic substrates or quartz substrates, and a refractive index of the second substrate 104 is substantially larger than a refractive index of air. The organic light-emitting diode device 108 is disposed on the first substrate 102, and a light emitting surface 108a of the organic light-emitting diode device 108 faces the first surface 104a of the second substrate 104. The dam 106 is disposed between the first substrate 102 and the second substrate 104 to combine the first substrate 102 and the second substrate 104, and the dam 106 surrounds the organic light-emitting diode device 108. Therefore, the first substrate 102, the second substrate 104, the organic light-emitting diode device 108 and the dam 106 form an enclosed space 110. In this exemplary embodiment, the enclosed space 110 is filled with air, but not limited thereto.

It is appreciated that, the first surface 104a of the second substrate 104 in the enclosed space 110 includes a plurality of concavities 112 arranged as a matrix, and at least one of the concavities 112 is disposed right above the light emitting surface 108a. In this exemplary embodiment, a part of the concavities 112 of the first surface 104a, i.e. a plurality of the concavities 112, are disposed right above the light emitting surface 108a, and another part of the concavities 112 do not overlap the light emitting surface 108a. Additionally, the first surface 104a of the second substrate 104 in each concavity 112 is a lens surface, and the second substrate 104 in each concavity 112 and the air in the enclosed space 110 form a concave lens surface. Therefore, the light emitted from the light emitting surface 108a of the organic light-emitting diode device 108 can be converged toward a normal line direction which is perpendicular to the second substrate 104, to reduce the occurrence of total reflection as the light moves into the external ambient from the second substrate 104 and increase the light extraction efficiency of the organic light-emitting diode package structure 100. The arrangement of the concavities 112 is not limited to square matrix arrangement; it could be hexagonal matrix arrangement as well.

In this exemplary embodiment, an opening of each concavity 112 is circle-shaped, and the concave lens surface is a spherical lens surface, but not limited thereto. Each concavity 112 has an opening diameter d1, and the opening diameter d1 of each of the concavities 112 is substantially smaller than 50 micrometers (μm), moreover, each concavity 112 has a depth d2, and the depth d2 of each of the concavities 112 is substantially smaller than 50 micrometers, therefore, each concavity 112 can have the enough small size to avoid the occurrence of light interference as the light passes through each of the concavities 112. Each of the concavities 112 has an opening area, and a ratio of a sum of the opening areas of the concavities 112 to an area of the first surface 104a of the second substrate 104 in the enclosed space 110, i.e. the fill factor, is substantially between 0 and 1. The ratio of the sum of the opening areas of the concavities 112 to the area of the first surface 104a in the enclosed space 110 is preferably as 1, so that the light emitted from the light emitting surface 108a of the organic light-emitting diode device 108 can be converged toward the normal line direction of the second substrate 104. Therefore, the light emitted from the light emitting surface 108a can be used efficiently, and the light extraction efficiency of the organic light-emitting diode package structure 100 can be increased. In other exemplary embodiments, an opening of each concavity could be other geometric pattern-shaped, and the concave lens surface could be prismatic lens surface, taper lens surface or elliptic lens surface.

The organic light-emitting diode device 108 includes a bottom electrode layer 114, an organic light-emitting layer 116, a top electrode layer 118 and a protection layer 120 sequentially disposed on the first substrate 102. In this exemplary embodiment, the light produced by the organic light-emitting diode device 108 is emitted from the protection layer 120, that is, the protection layer 120 having the light emitting surface 108a. The bottom electrode layer 114 may serve as a reflective electrode for example made of metal materials, and the light produced by the organic light-emitting layer 116 can be reflected by the bottom electrode layer 114 to move toward the second substrate 104, so that the light produced by the organic light-emitting layer 116 can be efficiently utilized. Accordingly, the organic light-emitting diode package structure 100 of this exemplary embodiment is an organic light-emitting diode package structure having a single light-emitting surface. The organic light-emitting diode package structure is not limited as illustrated above and could be any other types, for example, the protection layer may not include the light emitting surface, or a number of the organic light-emitting diode device could be plural.

It is appreciated that, since the plurality of concavities 112 are formed on the first surface 104a of the second substrate 104 and serve as concave lens surfaces, as the light emitted from the light emitting surface 108a moves into the second substrate 104, the light can be converged toward the normal line direction which is perpendicular to the second substrate 104, so that the occurrence of total reflection can be reduced, and the light extraction efficiency of the organic light-emitting diode package structure 100 can be increased. In the exemplary embodiment, since the organic light-emitting diode package structure 100 uses the concavities 112 to serve as lens surfaces (i.e. concave lens surfaces) to converge light, instead of convex lens surfaces, the light can be converged without using convex lens surfaces, and the overall thickness of the organic light-emitting diode package structure 100 may be decreased.

The organic light-emitting diode package structure of the present invention is not limited to the illustrated exemplary embodiment. To simplify the explanation and to clarify the comparison, the same components are denoted by the same numerals in the following exemplary embodiments or derivative embodiments, and the repeated parts are omitted herein for brevity.

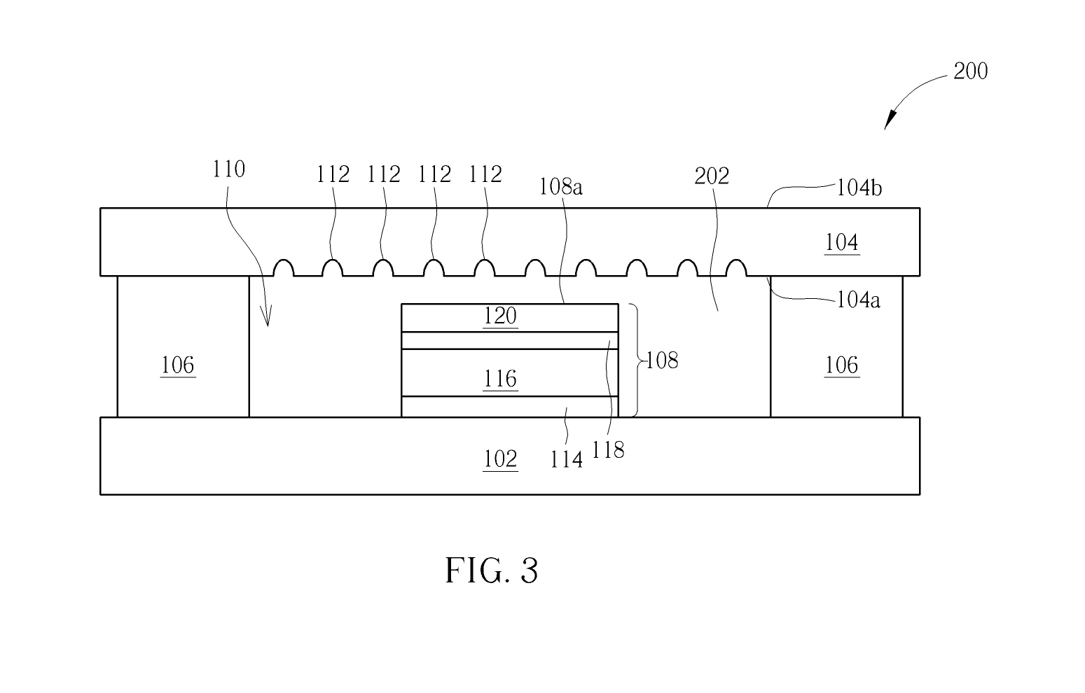

Please refer to FIG. 3. FIG. 3 illustrates a cross-sectional view of an organic light-emitting diode package structure according to a second exemplary embodiment of the present invention. As shown in FIG. 3, compared to the first exemplary embodiment, the organic light-emitting diode package structure 200 further includes a filling layer 202 covering the light emitting surface 108a of the organic light-emitting diode device 108 and filling the enclosed space 110. The second substrate 104 and the filling layer 202 jointly form the concave lens surface. In this exemplary embodiment, a refractive index of the filling layer 202 is substantially between a refractive index of the second substrate 104 and a refractive index of the protection layer 120 so as to efficiently reduce the occurrence of total reflection as the light produced by the organic light-emitting diode device 108 passes through the interface between the protection layer 120 and the enclosed space 110. Accordingly, the light extraction efficiency of the organic light-emitting diode package structure 200 is better than that of the organic light-emitting diode package structure 100 in the first exemplary embodiment. Furthermore, the refractive index of the filling layer 202 is preferably substantially between 1.6 and 2.0, but not limited thereto.

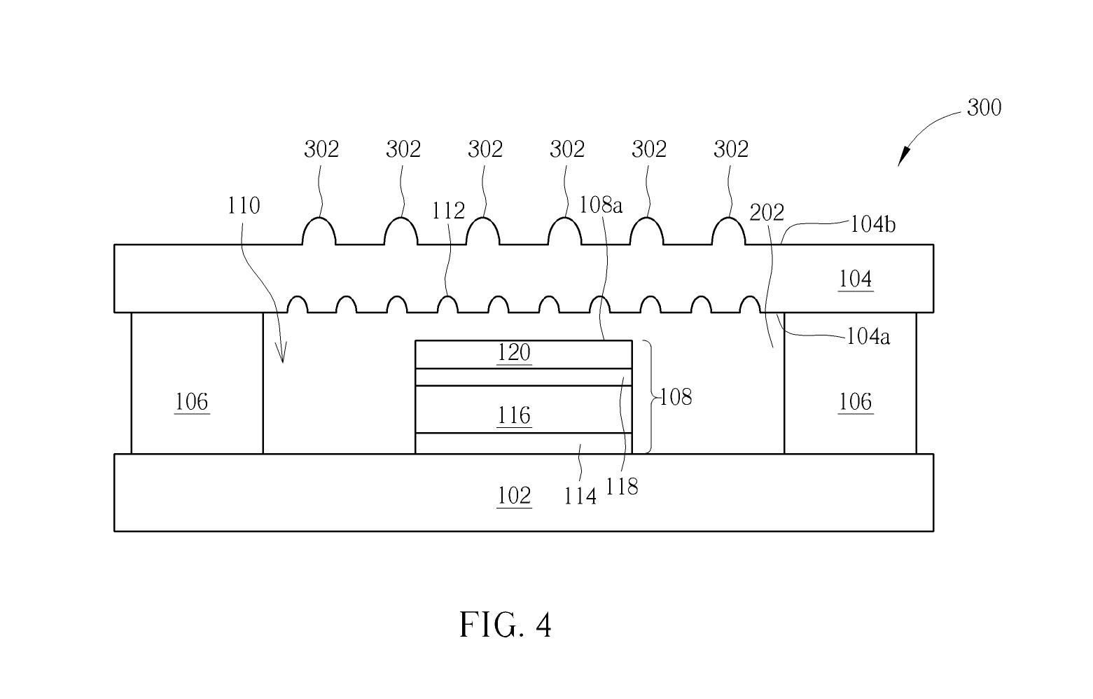

Please refer to FIG. 4. FIG. 4 illustrates a cross-sectional view of an organic light-emitting diode package structure according to a third exemplary embodiment of the present invention. As shown in FIG. 4, compared to the second exemplary embodiment, the organic light-emitting diode package structure 300 further includes a plurality of convex lens surfaces 302 disposed on the second surface 104b of the second substrate 104. Due to the disposition of the convex lens surfaces 302, the light moving into the external air ambient from the second substrate 104 can be converged toward a normal line direction of the second substrate 104 so as to reduce the occurrence of total reflection at the interface between the second substrate 104 and the air, which may increase the light extraction efficiency of the organic light-emitting diode package structure 300. In this exemplary embodiment, the convex lens surfaces 302 are disposed right above the light emitting surface 108a to efficiently converge the light right above the light emitting surface 108a.

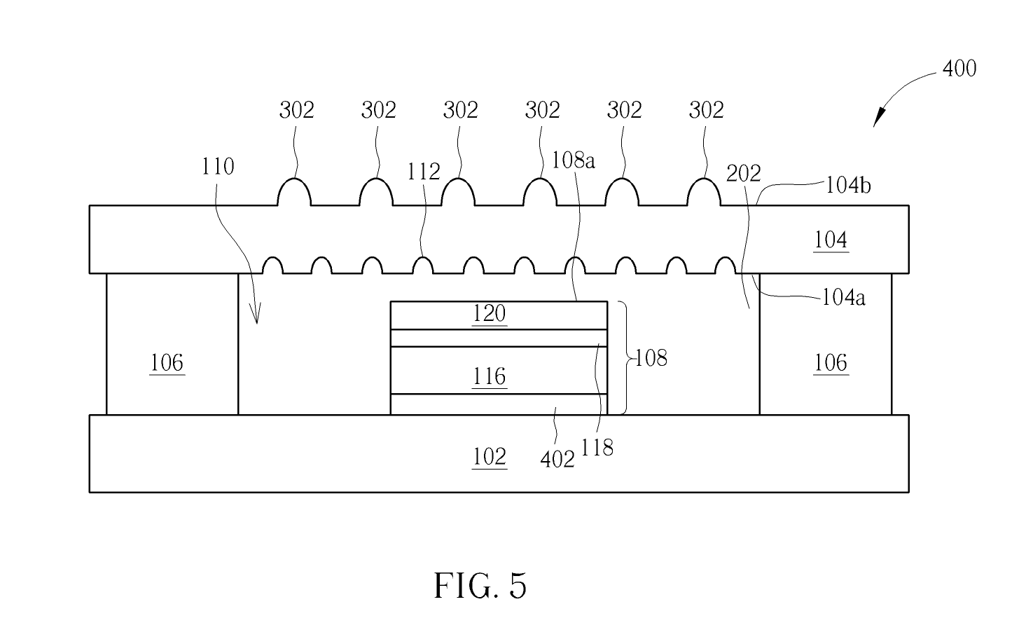

Please refer to FIG. 5. FIG. 5 illustrates a cross-sectional view of an organic light-emitting diode package structure according to a fourth exemplary embodiment of the present invention. As shown in FIG. 5, compared to the third exemplary embodiment, the bottom electrode layer 402 of the organic light-emitting diode package structure 400 includes a transparent electrode. Therefore, the light produced by the organic light-emitting layer 116 can penetrate through the bottom electrode layer 402 and the first substrate 102 and emit toward the outside of the first substrate 102. Accordingly, the organic light-emitting diode package structure 400 of this exemplary embodiment is an organic light-emitting diode package structure having double light-emitting surfaces.

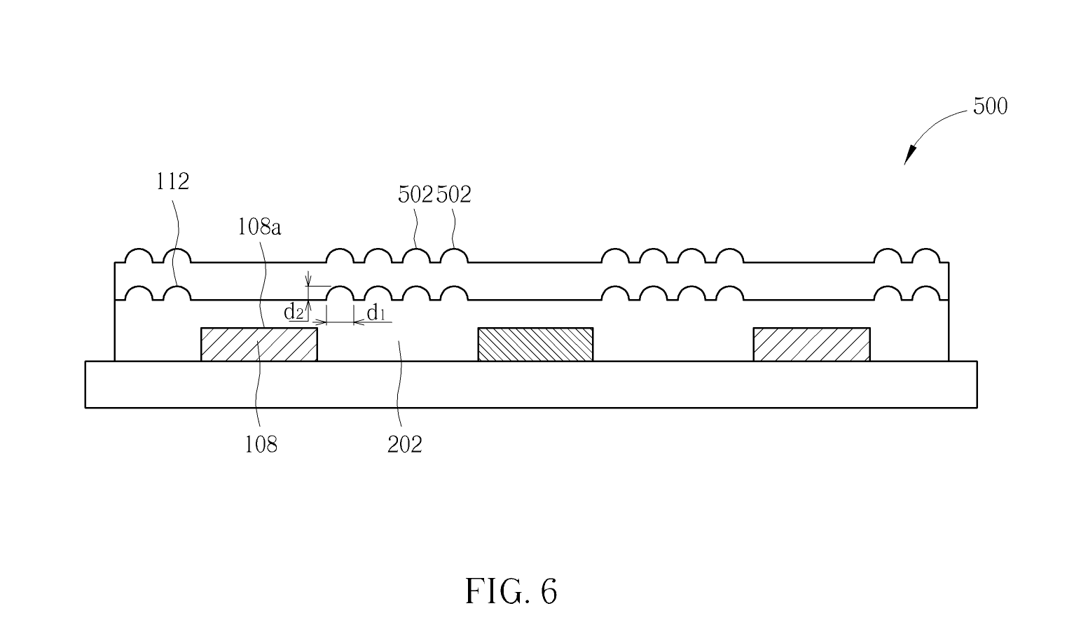

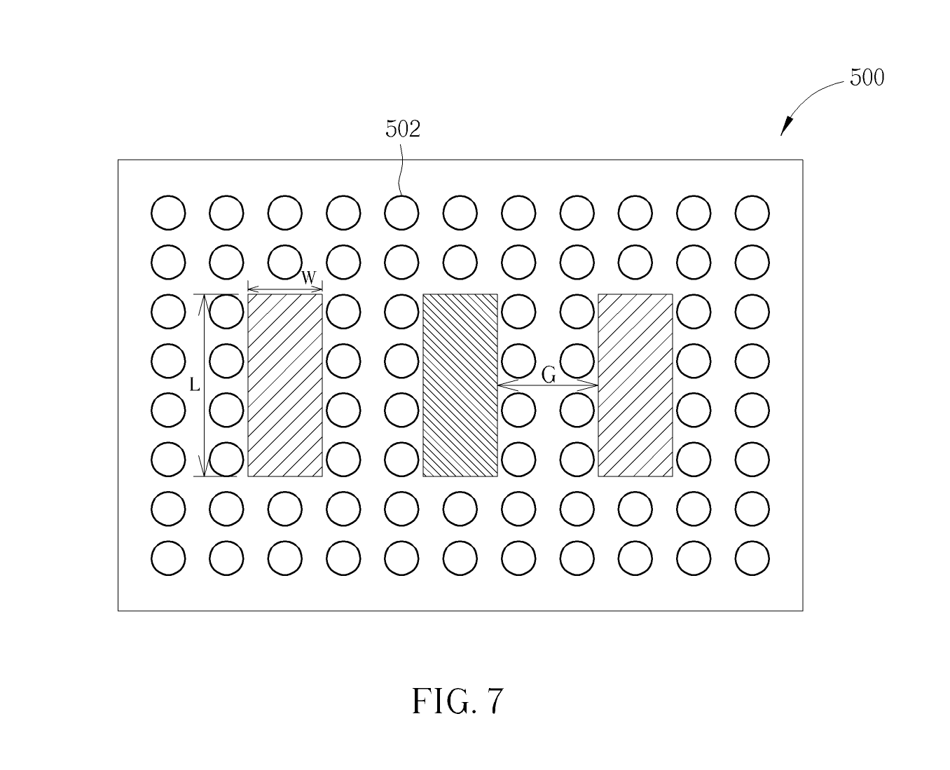

The organic light-emitting diode package structure of the present invention can be applied in the organic light-emitting diode display devices, in other words, the organic light-emitting diode package structure may include a plurality of organic light-emitting diode devices to serve as a pixel or a sub-pixel, and the organic light-emitting diode devices are disposed between the first substrate and the second substrate. Please refer to FIG. 6 and FIG. 7. FIG. 6 illustrates a cross-sectional view of an organic light-emitting diode package structure according to a fifth exemplary embodiment of the present invention. FIG. 7 illustrates a top view of an organic light-emitting diode package structure according to a fifth exemplary embodiment of the present invention. As shown in FIG. 6 and FIG. 7, compared to the third exemplary embodiment, the convex lens surfaces 502 and the concavities 112 are not disposed right above the light emitting surfaces 108a, but surround the regions right above the light emitting surfaces 108a. The organic light-emitting diode package structure 500 includes a plurality of organic light-emitting diode devices 108 disposed between the first substrate 102 and the filling layer 202. In this exemplary embodiment, each of the organic light-emitting diode devices 108 may correspond to a single sub-pixel, and every three organic light-emitting diode devices 108 form a pixel. The organic light-emitting diode devices 108 in the same pixel may generate different colors, for example, red, green and blue which could be mixed to be white, but not limited thereto. The opening diameter d1 of each of the concavities 112 is substantially smaller than a length L of the organic light-emitting diode device 108, a width W of the organic light-emitting diode device 108, and the interval G between two neighboring organic light-emitting diode devices 108, moreover, the depth d2 of each of the concavities 112 is substantially smaller two times the opening diameter d1 of each of the concavities 112. In other exemplary embodiments, an organic light-emitting diode device 108 may correspond to a pixel, and the single organic light-emitting diode device 108 may generate different colors, but not limited thereto.

It is appreciated that, as the convex lens surfaces and/or the concavities are disposed right above the light emitting surfaces, the light generated by the two neighboring organic light-emitting diode devices of the organic light-emitting diode package structure may be mixed, and the images generated by the two neighboring pixels of the organic light-emitting diode package structure may interfere with each other to form unclear images. Accordingly, the convex lens surfaces and the concavities disposed right above the light emitting surfaces 108a of the organic light-emitting diode device 108 are removed in the organic light-emitting diode package structure 500 to avoid the interference of the images generated by the two neighboring pixels. When the light emitted by the organic light-emitting diode device 108 moves to the interface between the second substrate 104 and the air where is farther away from the organic light-emitting diode device 108, an incident angle of the light becomes larger, and the total reflection would occur more easily. Accordingly, the convex lens surfaces 502 and the concavities 112 disposed in the region without overlapping the light emitting surfaces 108a in the organic light-emitting diode package structure 500 may avoid the occurrence of total reflection which is cause by that the incident angle of light is close to or larger than the critical angle of total reflection, and more light may be emitted to the outside. Therefore, the light extraction efficiency of the organic light-emitting diode package structure 500 is increased.

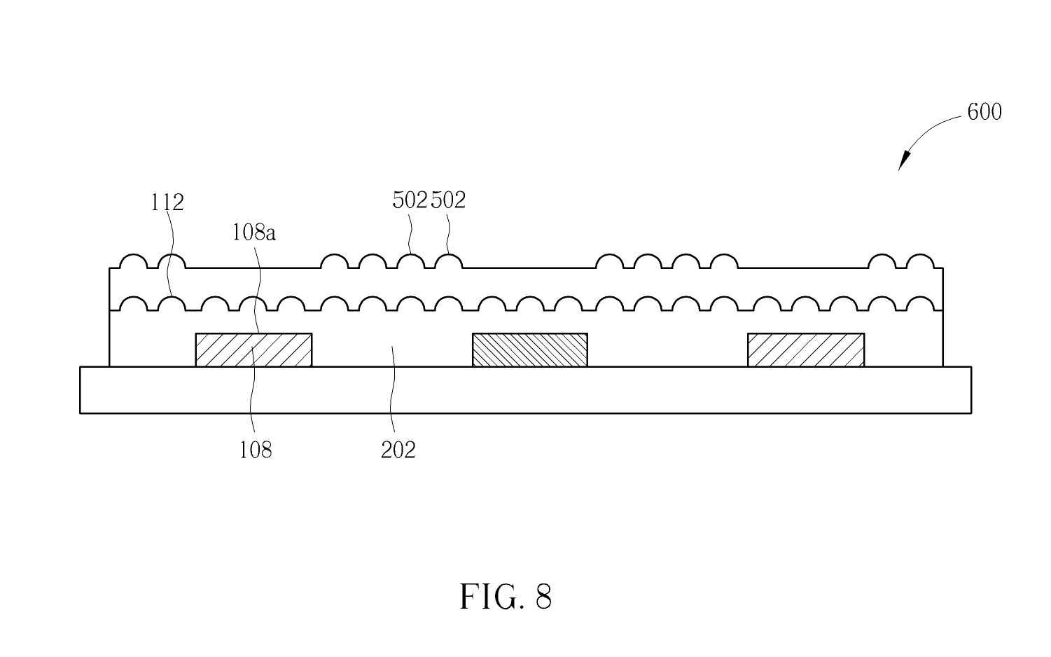

Please refer to FIG. 8. FIG. 8 illustrates a cross-sectional view of an organic light-emitting diode package structure according to a sixth exemplary embodiment of the present invention. As shown in FIG. 8, compared to the fifth exemplary embodiment, the concavities 112 are disposed right above the light emitting surfaces 108a to overlap the light emitting surfaces 108a.

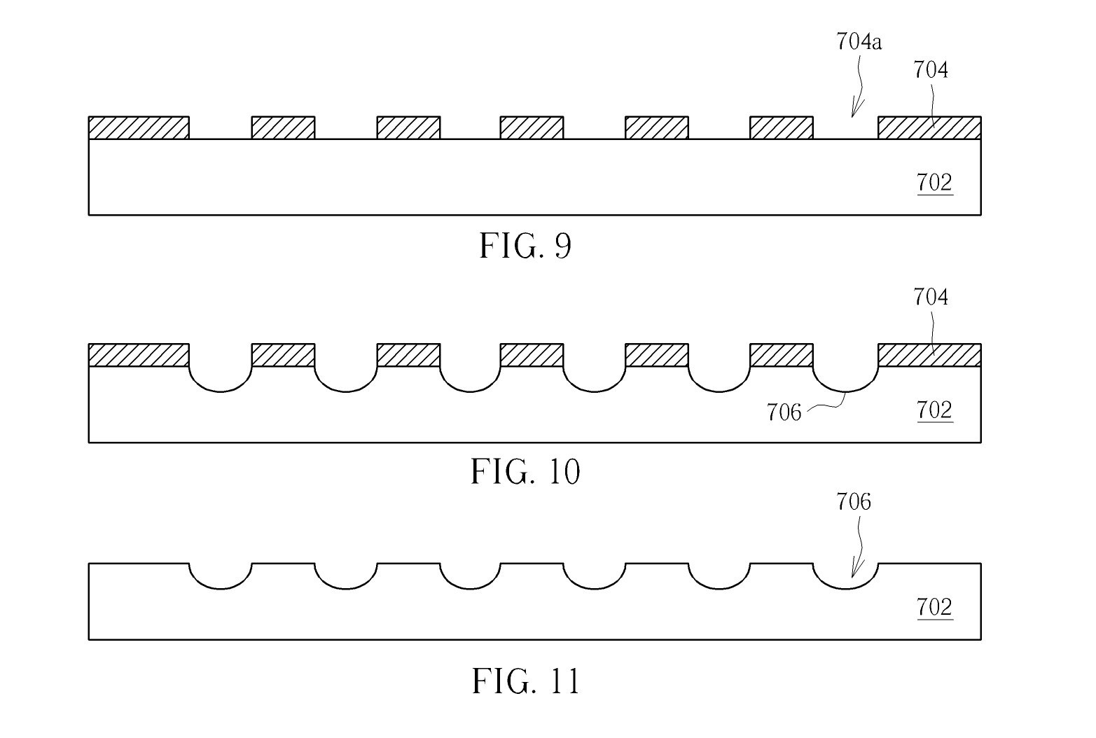

The present invention also provides a method of forming concavities on a substrate to form concavities on the second substrate. Please refer to FIG. 9 through FIG. 11. FIG. 9 through FIG. 11 illustrate schematic diagrams of a method of forming concavities according to a preferred exemplary embodiment of the present invention. As shown in FIG. 9, a substrate 702, such as a glass substrate, a plastic substrate or a quartz substrate, is provided. Then, a deposition process and a photolithographic process are performed to form a photoresist pattern 704 on the substrate 702, and the photoresist pattern 704 includes a plurality of openings 704a exposing the substrate 702. As shown in FIG. 10, an etching process is performed to etch the substrate 702 through each of the openings 704a to form a plurality of concavities 706 on the substrate 702. In this exemplary embodiment, the etching process could be isotropic etching process or anisotropic etching process, and the formed concavities 706 are arc-shaped to serve as concave lens surfaces. As shown in FIG. 11, the photoresist pattern 704 is removed. Afterwards, a glass tempering process is selectively performed on the substrate 702 having the concavities 706. In this exemplary embodiment, the glass tempering process including putting the substrate 702 having the concavities 706 into the solution, and the ions having the larger volume in the solution is used to replace the ions having the smaller volume originally in the substrate 702, for example, potassium (K) ion is used to replace sodium (Na) ion, so as to intensify the strength of the substrate 702.

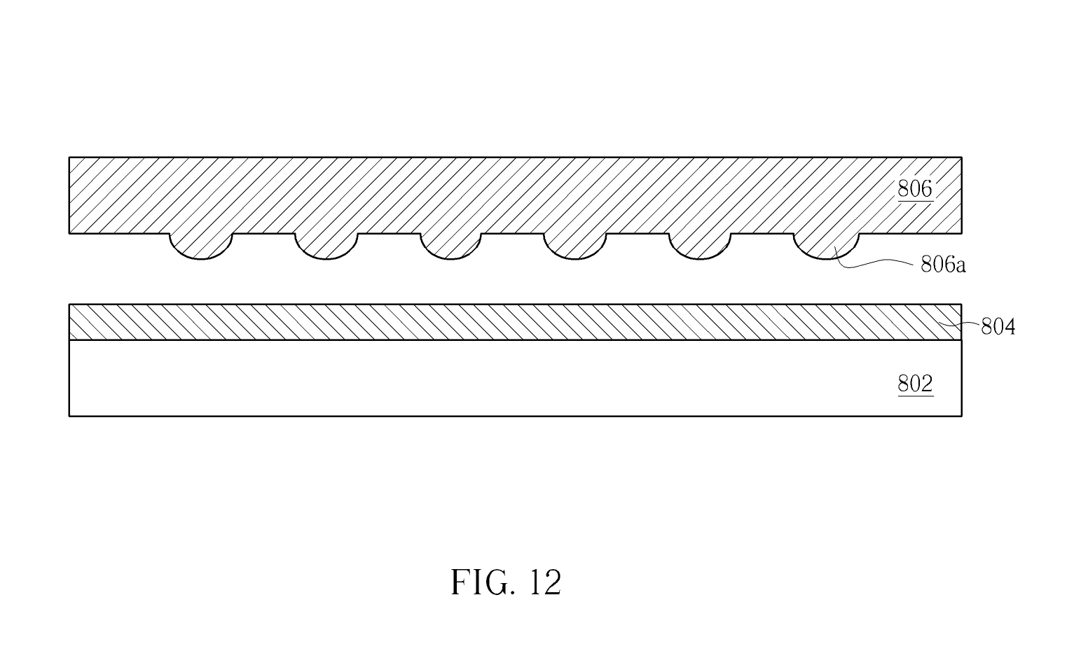

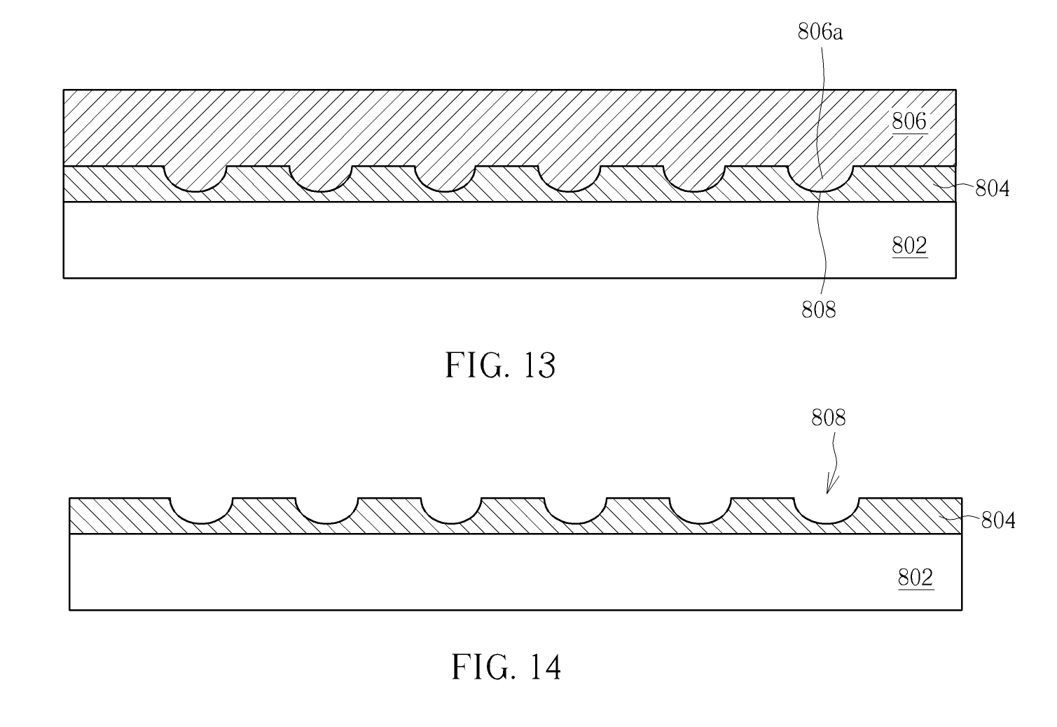

The method of forming concavities is not limited to the illustrated exemplary embodiment. Please refer to FIG. 12 through FIG. 14. FIG. 12 through FIG. 14 illustrate schematic diagrams of a method of forming concavities according to another preferred exemplary embodiment of the present invention. As shown in FIG. 12, a substrate 802, such as a glass substrate, a plastic substrate or a quartz substrate, is provided. Then, a coating process is performed to coat an adhesive film 804 on the substrate 802, and the adhesive film 804 may include ultraviolet (UV) adhesive film. Furthermore, a mold 806 is provided, and the mold 806 includes a plurality of protrusions 806a such as hemispheric protrusions. As shown in FIG. 13, a stamping process is performed, and a surface including the protrusions 806a of the mold 806 is pressed to the adhesive film 804 to form a plurality of concavities 808 in the adhesive film 804. Subsequently, a curing process, such as the ultraviolet (UV) curing process or the thermal curing process, is performed to cure the adhesive film 804, therefore, the concavities 808 can be fixed in the adhesive film 804. In this exemplary embodiment, the adhesive film 804 is an UV adhesive film, and the UV curing process is performed to expose the adhesive film 804 to ultraviolet to cure the adhesive film 804. Afterward, as shown in FIG. 14, the mold 806 is removed. In other exemplary embodiments, a material of the adhesive film may include thermal curing material, and the curing process may include the thermal curing process, but not limited thereto.

In conclusion, the concavities are formed on the first surface of the second substrate to serve as concave lens surfaces. The disposition of the concavities can converge light toward the normal line direction of the second substrate 104 and reduce the occurrence of total reflection, as the light emitted from the light emitting surface of the organic light-emitting diode device moves into the second substrate, to increase the light extraction efficiency of the organic light-emitting diode package structure. Furthermore, the concavities are used as the lens surfaces to converge light rather than convex lens surface in the organic light-emitting diode package structure, which may validly reduce the overall thickness of the organic light-emitting diode package structure

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic light-emitting diode package structure, comprising:
a first substrate;
a second substrate having a first surface and a second surface, and the first surface of the second substrate and the first substrate being disposed opposite to each other, wherein the first surface of the second substrate comprises a plurality of concavities, each of the concavities has an opening area, and a ratio of a sum of the opening areas of the concavities to an area of the first surface of the second substrate is substantially between 0 and 1;
at least an organic light-emitting diode device, disposed on the first substrate, wherein a light emitting surface of the organic light-emitting diode device faces the second substrate; and
a dam, disposed between the first substrate and the second substrate to combine the first substrate and the second substrate, wherein the dam surrounds the organic light-emitting diode device.

2. The organic light-emitting diode package structure according to claim 1, wherein the first substrate, the second substrate, the organic light-emitting diode device and the dam form an enclosed space.

3. The organic light-emitting diode package structure according to claim 2, wherein the enclosed space is filled with air.

4. The organic light-emitting diode package structure according to claim 2, further comprising a filling layer covering the light emitting surface of the organic light-emitting diode device, wherein the filling layer fills the enclosed space.

5. The organic light-emitting diode package structure according to claim 4, wherein the organic light-emitting diode device comprises a protection layer having the light emitting surface, and a refractive index of the filling layer is substantially between a refractive index of the second substrate and a refractive index of the protection layer.

6. The organic light-emitting diode package structure according to claim 5, wherein the refractive index of the filling layer is substantially between 1.6 and 2.0.

7. The organic light-emitting diode package structure according to claim 1, wherein an opening diameter of each of the concavities is substantially smaller than 50 micrometers (μm).

8. The organic light-emitting diode package structure according to claim 1, wherein a depth of each of the concavities is substantially smaller than 50 micrometers.

9. The organic light-emitting diode package structure according to claim 1, wherein the first surface of the second substrate in each concavity is a lens surface.

10. The organic light-emitting diode package structure according to claim 1, wherein at least one of the concavities is disposed right above the light emitting surface.

11. The organic light-emitting diode package structure according to claim 1, wherein the concavities are not disposed right above the light emitting surface.

12. The organic light-emitting diode package structure according to claim 1, wherein the second surface of the second substrate comprises a plurality of convex lens surfaces.

13. The organic light-emitting diode package structure according to claim 12, wherein the convex lens surfaces are not disposed right above the light emitting surface.

14. The organic light-emitting diode package structure according to claim 1, wherein the organic light-emitting diode device comprises a bottom electrode layer and an organic light-emitting layer sequentially disposed on the first substrate.

15. The organic light-emitting diode package structure according to claim 14, wherein the bottom electrode layer comprises a reflective electrode.

16. The organic light-emitting diode package structure according to claim 14, wherein the bottom electrode layer comprises a transparent electrode.

17. A method of forming concavities on a substrate, comprising:
providing a substrate;
forming a photoresist pattern on the substrate, wherein the photoresist pattern comprises a plurality of openings exposing the substrate;
performing an etching process to etch the substrate through the openings to form a plurality of concavities; and
removing the photoresist pattern.

18. The method of forming concavities on the substrate according to claim 17, wherein the etching process comprises an isotropic etching process or an anisotropic etching process.

19. A method of forming concavities on a substrate, comprising:
providing a substrate;
coating an adhesive film on the substrate;
providing a mold, wherein the mold comprises a plurality of protrusions;
pressing a surface comprising the protrusions of the mold to the adhesive film to form a plurality of concavities in the adhesive film;
performing a curing process to cure the adhesive film; and
removing the mold.

20. The method of forming concavities on the substrate according to claim 19, wherein the curing process comprises an ultraviolet (UV) curing process or a thermal curing process.
